(19) United States
(12) Patent Application Publication
(10) Pub. No.: US 2025/0380481 A1
(43) Pub. Date: Dec. 11, 2025

(54) INTEGRATED CIRCUIT DEVICE

(71) Applicant: SAMSUNG ELECTRONICS CO., LTD., Suwon-si (KR)

(72) Inventors: Seungmin CHA, Suwon-si (KR); Goun KANG, Suwon-si (KR); Minchan GWAK, Suwon-si (KR)

(73) Assignee: SAMSUNG ELECTRONICS CO., LTD., Suwon-si (KR)

(21) Appl. No.: 19/013,296

(22) Filed: Jan. 8, 2025

(30) Foreign Application Priority Data
Jun. 5, 2024 (KR) 10-2024-0073926

(51) Int. Cl. H10D 64/23; H10D 30/00; H10D 30/40; H10D 84/83

(52) U.S. Cl. CPC H10D 64/258; H10D 30/40; H10D 30/502; H10D 84/832

(57) ABSTRACT

An integrated circuit device includes an insulating structure, a first source/drain region on the insulating structure, a second source/drain region on the insulating structure and spaced apart from the first source/drain region, a gate structure including at least one gate electrode layer, the gate structure being between the first source/drain region and the second source/drain region, a contact plug connected to the gate structure, a first backside source/drain contact structure penetrating the insulating structure and connected to the first source/drain region, an electrical insulating layer on a side wall of an end portion of the first backside source/drain contact structure, the electrical insulating layer contacting the first source/drain region, and a first semiconductor material layer on the electrical insulating layer, where the electrical insulating layer is configured to electrically insulate the first semiconductor material layer from the first backside source/drain contact structure.

### CROSS-REFERENCE TO RELATED APPLICATION

This application is based on and claims priority to Korean Patent Application No. 10-2024-0073926, filed on Jun. 5, 2024, in the Korean Intellectual Property Office, the disclosure of which is incorporated by reference herein in its entirety.

### BACKGROUND

Example embodiments of the disclosure relate to an integrated circuit device, and more particularly, to an integrated circuit device in which a power delivery network (PDN) is formed on a backside of the integrated circuit device.

As electronic technology develops, down-scaling of the integrated circuit device is rapidly progressing. In order to efficiently deliver power to highly integrated circuit devices, integrated circuit devices having a PDN on the backside of the integrated circuit devices are being introduced. Since these integrated circuit devices not only have complex structures but also are highly dense, the reliability of the operation may be reduced due to leakage current, and therefore, integrated circuit devices with improved reliability of the operation are required.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an integrated circuit device with improved reliability and a method of manufacturing the same.

Additional aspects will be set forth in part in the description which follows and, in part, will be apparent from the description, or may be learned by practice of the presented embodiments.

According to an aspect of an example embodiment, an integrated circuit device may include an insulating structure, a first source/drain region on the insulating structure, a gate structure including at least one gate electrode layer, the gate structure adjacent to the first source/drain region on the insulating structure, a contact plug connected to the gate structure, a backside source/drain contact structure penetrating the insulating structure and connected to the first source/drain region, an electrical insulating layer on a side wall of an end portion of the backside source/drain contact structure, the electrical insulating layer contacting the first source/drain region, and a semiconductor material layer on the electrical insulating layer, where the electrical insulating layer is configured to electrically insulate the semiconductor material layer from the backside source/drain contact structure.

According to an aspect of an example embodiment, an integrated circuit device may include an insulating structure, a first source/drain region on the insulating structure, a second source/drain region on the insulating structure and spaced apart from the first source/drain region, a gate structure including at least one gate electrode layer, the gate structure being between the first source/drain region and the second source/drain region, a contact plug connected to the gate structure, a first backside source/drain contact structure penetrating the insulating structure and connected to the first source/drain region, an electrical insulating layer on a side wall of an end portion of the first backside source/drain contact structure and contacts the first source/drain region, and a first semiconductor material layer on the electrical insulating layer, where the electrical insulating layer is configured to electrically insulate the first semiconductor material layer from the first backside source/drain contact structure.

According to an aspect of an example embodiment, an integrated circuit device may include an insulating structure, a first source/drain region on the insulating structure, a second source/drain region on the insulating structure and spaced apart from the first source/drain region, a gate structure including a gate electrode layer, the gate structure being between the first source/drain region and the second source/drain region, a contact plug connected to the gate structure, a first backside source/drain contact structure penetrating the insulating structure and connected to the first source/drain region, a second backside source/drain contact structure penetrating the insulating structure and connected to the second source/drain region, an electrical insulating layer on at least one of a side wall of an end portion of the first backside source/drain contact structure and a side wall of an end portion of the second backside source/drain contact structure, and a semiconductor material layer on the electrical insulating layer, where at least a portion of the semiconductor material layer having a thickness less than 2 nm is on the insulating structure between the first backside source/drain contact structure and the second backside source/drain contact structure.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram of an integrated circuit device according to one or more embodiments;

FIGS. 2A to 2D are cross-sectional views of examples of integrated circuit devices taken along line I-I′ of FIG. 1 according to one or more embodiments;

FIGS. 3A to 3D are cross-sectional views of examples of integrated circuit devices taken along the line I-I′ of FIG. 1 according to one or more embodiments;

FIGS. 4 to 23 are cross-sectional views sequentially illustrating of manufacturing an integrated circuit device according to one or more embodiments;

FIGS. 24 to 27 are cross-sectional views sequentially illustrating operations of manufacturing an integrated circuit device according to one or more embodiments;

FIGS. 28 to 34 are cross-sectional views sequentially illustrating operations of manufacturing an integrated circuit device according to one or more embodiments;

FIGS. 35 to 38 are cross-sectional views sequentially illustrating operations of manufacturing an integrated circuit device according to one or more embodiments;

FIG. 39 is a cross-sectional view illustrating an integrated circuit device corresponding to FIG. 38, according to one or more embodiments;

FIG. 40 is a graph showing a simulation of the magnitude of leakage current depending on the thickness of silicon residue remaining after a removal process of a bulk substrate according to one or more embodiments;

FIG. 41 is a bottom plan view taken at “H” level of FIG. 39 according to one or more embodiments; and

FIG. 42 is a bottom plan view taken at “H” level of FIG. 27 according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

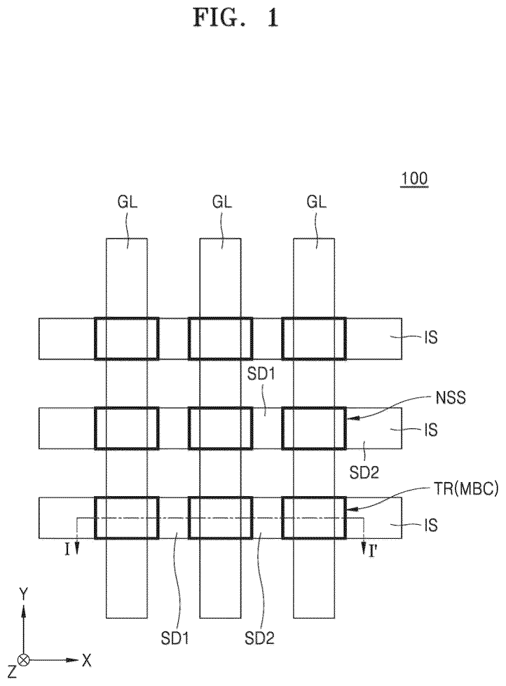

FIG. 1 is a diagram of an integrated circuit device 100 according to one or more embodiments.

Referring to FIG. 1, an X direction may be a first horizontal direction, and a Y direction may be a second horizontal direction perpendicular to the first horizontal direction. A Z direction may be a vertical direction perpendicular to a plane created by the X and Y directions. Hereinafter, the layout of the integrated circuit device 100 will be described in detail, and embodiments are not limited to the layout of FIG. 1.

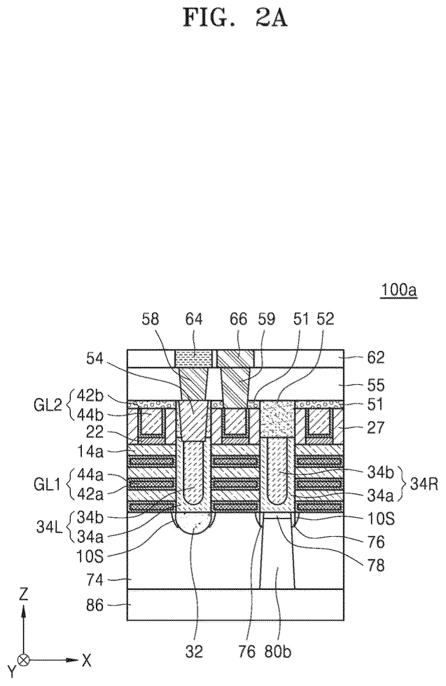

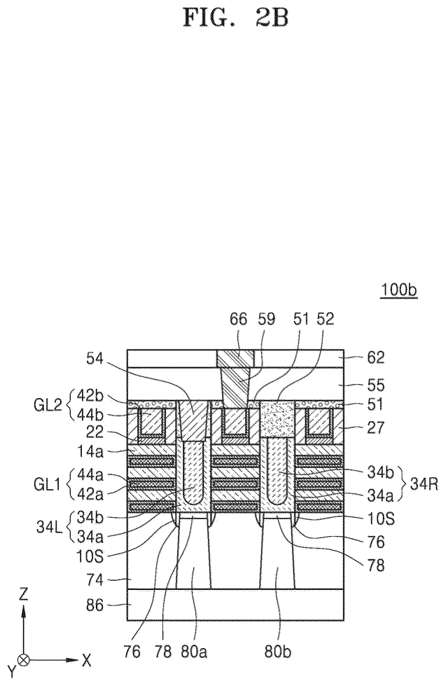

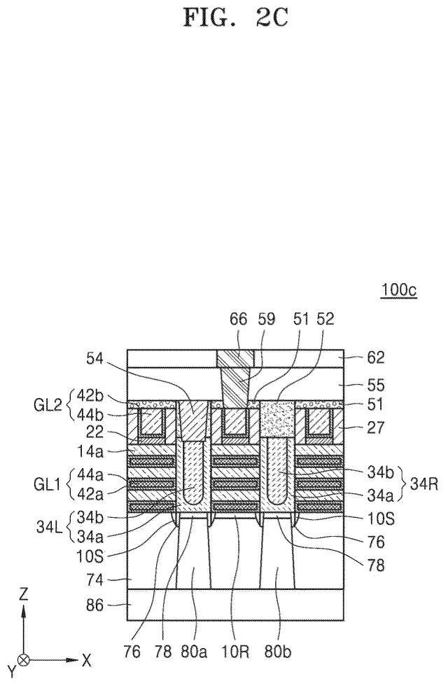

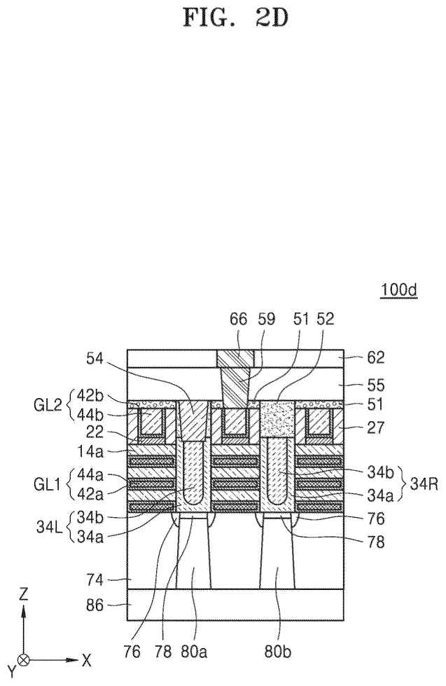

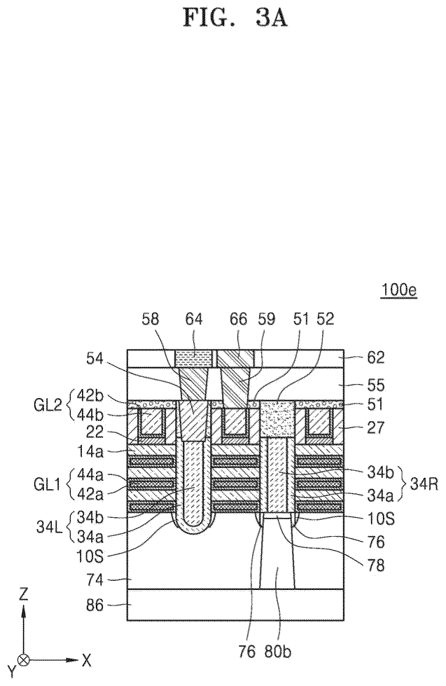

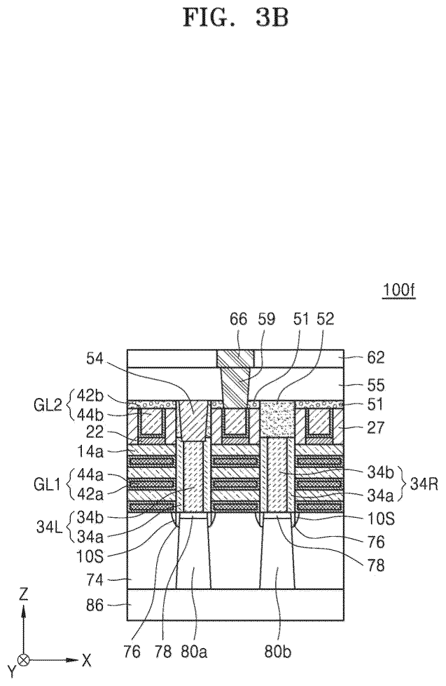

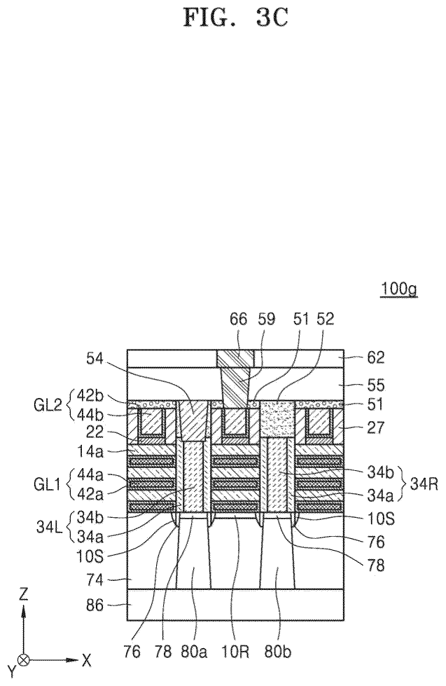

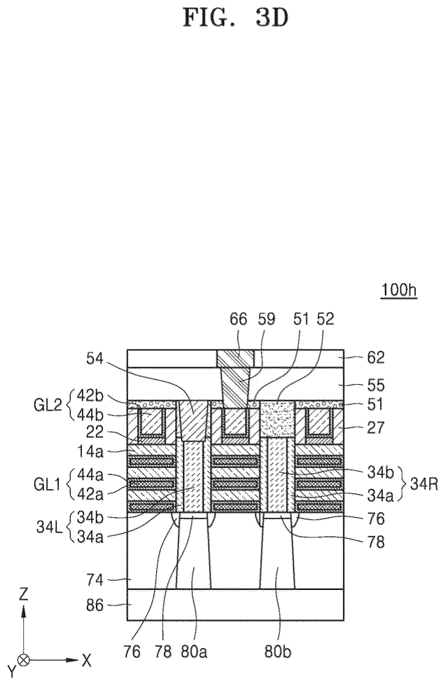

The integrated circuit device 100 may include a plurality of insulating structure IS extending in the first horizontal direction (X direction) and spaced apart from each other at a predetermined interval in the second horizontal direction (Y direction). The insulating structure IS is indicated by reference number ‘74’ in FIGS. 2A to 3D. The insulating structure IS may be a structure of an insulating material having a shape of an active fin that are formed after the active fin is replaced with the insulating material in a subsequent process, in which the active fin may extend in the first horizontal direction and may be defined by a field insulating layer (for example, a device isolation insulating layer) on an upper side of a substrate. Accordingly, the device isolation insulating layer extending in the first horizontal direction may be formed between adjacent insulating structures IS. When the insulating structure IS includes the same material as the device isolation insulating layer, a boundary between the insulating structure IS and the device isolation insulating layer may not be identified. For example, the insulating structure IS and the device isolation insulating layer may form the same insulating layer without distinction. In addition, the integrated circuit device 100 may include a plurality of gate lines GL that extend in the second horizontal direction (Y direction) perpendicular to the first horizontal direction (X direction) and are spaced apart from each other in the first horizontal direction (X direction) at a predetermined interval. Herein, the gate line GL may indicate the gate line itself for signal transmission. Alternatively, the gate line GL may be referred to in a broad sense as including a gate structure that includes a gate electrode, a gate insulating layer, a gate spacer, and a gate capping layer at a unit transistor position connected to the gate line.

Nanosheet stacking structures NSS may be arranged in overlapping portions where the insulating structures IS and the gate lines GL intersect in the integrated circuit device 100. A first source/drain region SD1 may be formed on one side of the nanosheet stacking structure NSS, and a second source/drain region SD2 may be formed on the other side of the nanosheet stacking structure NSS. FIG. 1 is a diagram schematically illustrating the relative positional relationship between the nanosheet stacking structure NSS, and the first source/drain region SD1 and the second source/drain region SD2. The relative position relationship of the first source/drain region SD1 and the second source/drain region SD2 in the second horizontal direction (Y direction) with respect to the nanosheet stacking structure NSS may vary.

Transistors TR including the nanosheet stacking structure NSS and a gate electrode surrounding the nanosheet stacking structure NSS in the overlapping portions where the insulating structures IS and the gate lines GL intersect in the integrated circuit device 100, may be formed. The transistors TR may be three-dimensional transistors. The nanosheet stacking structure NSS may include a plurality of nanosheets, each including an active region in a nanosheet structure. The nanosheet stacking structure and the gate electrode that surrounds the nanosheet stacking structure may form a multi-bridge channel field effect transistor (MBCFET). In one or more embodiments, the active region may be a nanowire shape. In some embodiments, the transistor TR may include a single transistor including a single gate electrode layer. For example, the transistor TR may include a P-type transistor or an N-type transistor.

FIG. 2A is a cross-sectional view of an example integrated circuit device 100a taken along line I-I′ of FIG. 1 according to one or more embodiments. FIG. 2A shows that a backside source/drain contact structure is electrically connected to a second source/drain region 34R (e.g., for power supply), and a frontside source/drain contact structure is electrically connected to a first source/drain region 34L (e.g., for signal transmission).

Referring to FIG. 2A, the integrated circuit device 100a may include an insulating structure 74. Gate structures GL1 and GL2 may be formed on the insulating structure 74 along an upper direction or along a frontside direction (i.e., Z direction), based on the insulating structure 74. The gate structures GL1 and GL2 may include a gate electrode layer and a gate insulating layer surrounding the gate electrode layer. The nanosheet stacking structure NSS may be arranged between a plurality of gate electrode layers stacked vertically, and may refer to a plurality of active regions having the nanosheet structure. That is, the nanosheet stacking structure NSS may include a plurality of nanosheets. A channel layer may be formed in an active region, and the active region may be referred to as a channel layer (or a gate channel layer). Thus, the gate structures GL1 and GL2 may include the gate electrode layer and the gate insulating layer, in which the gate insulating layer surrounds the gate electrode layer between the gate electrode and the active region which acts as the channel layer.

In FIG. 2A, a first gate structure GL1 arranged at a lower portion of a front side may include a plurality of first gate electrode layers 44a and a plurality of first gate insulating layers 42a that are stacked on the insulating structure 74. Each first gate electrode layer 44a, each first gate insulating layer 42a contacting each first gate electrode layer 44a, and each channel layer 14a (e.g., nanosheet) that corresponds to the first gate electrode layer 44a with the first gate insulating layer 42a therebetween may form one transistor together with source/drain regions arranged on the left and right thereof. In FIG. 2A, the first gate structure GL1 shows that three gate electrode layers 44a are formed in a vertical direction, but embodiments are not limited thereto, and the number of first gate electrode layers 44a may vary (i.e., be less or more than three).

As shown in FIG. 2A, a second gate structure GL2 may be formed on the first gate structure GL1 (that is, at an uppermost portion of the front side). The second gate structure GL2 may include a second gate insulating layer 42b and a second gate electrode layer 44b. The channel layer 14a (e.g., a nanosheet), the second gate insulating layer 42b, and the second gate electrode layer 44b that are arranged on an upper portion of the front side may form one transistor together with the source/drain regions arranged at left and right sides thereof. Accordingly, the first gate structure GL1 and the second gate structure GL2, and the plurality of channel layers 14a (e.g., the plurality of nanosheets) between the first and second gate structures GL1 and GL2 may form one transistor together with the source/drain regions arranged on the left and right sides thereof.

A spacer insulating layer 27 may be formed as a gate spacer on side walls of the second gate structure GL2. FIG. 2A shows the insulating layer 22 as a separate component between the second gate insulating layer 42b and the channel layer 14a. In one or more embodiments, the insulating layer 22 may be combined with the second gate insulating layer 42b to constitute a single insulating layer. As described below, the second gate structure GL2 may be formed according to a different manufacturing method than that of the first gate structure GL1, and thus may have a different shape from that of the first gate structure GL1. For the convenience of the description, the first gate structure GL1 and the second gate structure GL2 may be referred to as simply the gate structure GL. In one or more embodiments, the second gate structure GL2 may be absent.

Source/drain regions 34L and 34R may be formed adjacent to side walls of the first gate structure GL1. The source/drain region 34L and 34R may be arranged at regular intervals in an extension direction of the insulating structure IS (that is, in the first horizontal direction (X direction)), as shown in FIG. 1. In FIG. 2A, based on the first gate structure GL1 arranged in a center of FIG. 2A, the source/drain region shown on the left side may be referred to a first source/drain region 34L and the source/drain region shown on the right side may be referred to a second source/drain region 34R. The first and second sources/drain regions 34L and 34R may be self-aligned to side walls of the first gate structure GL1.

The source/drain region 34L and 34R may include, for example, an inner source/drain region 34b arranged in an inner side thereof and an outer source/drain region 34a surrounding the inner source/drain region 34b. The inner source/drain region 34b and the outer source/drain region 34a may be distinguished from each other by the difference in impurity concentration. In one or more embodiments, each of the source/drain regions 34L and 34R may be formed as a single source/drain region structure with the same impurity concentration.

A second contact plug 59 that penetrates a gate capping layer 51 and a second interlayer insulating layer 55, and that is electrically connected to the second gate electrode layer 44b of the second gate structure GL2, may be formed on the second gate structure GL2 located between the first and second source/drain regions 34L and 34R. A gate connection wiring layer 66 that penetrates a third interlayer insulating layer 62 and that is electrically connected to the second contact plug 59 may be formed on the second contact plug 59. The second contact plug 59 and the gate connection wiring layer 66 may constitute a frontside gate conductive line that may apply an operating voltage to the gate electrode layers 44a and 44b of the first and/or second gate structures GL1 and GL2 through a gate line. The second contact plug 59 may be referred to as a frontside gate contact structure.

A first interlayer insulating layer 52, a second interlayer insulating layer 55, and a third interlayer insulating layer 62 may be formed on the second source/drain region 34R that is arranged at the right side of the first gate structure GL1. A first contact plug 54 that penetrates the first interlayer insulating layer 52 and that is electrically connected to the first source/drain region 34L may be formed on the first source/drain region 34L that is arranged at the left side of the first gate structure GL1. A first via plug 58 that penetrates the second interlayer insulating layer 55 and that is electrically connected to the first contact plug 54 may be formed on the first contact plug 54. A source/drain connection wiring layer 64 that penetrates the third interlayer insulating layer 62 and that is electrically connected to the first via plug 58 may be formed on the first via plug 58. The first contact plug 54, the first via plug 58, and the source/drain connection wiring layer 64 may constitute a frontside source/drain conductive line that may apply the operating voltage to the first source/drain region 34L. The first contact plug 54 and the first via plug 58 may be referred to as a frontside source/drain contact structure.

The integrated circuit device 100a according to one or more embodiments may not include the second gate structure GL2. In this case, the second contact plug 59 may be electrically connected to the first gate electrode layer 44a located at a top of the first gate structure GL1.

A power supply rail 86 for supplying power to the second source/drain 34R may be formed on a lower surface of the insulating structure 74. The power supply rail 86 may be electrically connected to the second source/drain region 34R through a second backside source/drain contact structure 80b that penetrates the insulating structure 74. As shown in FIG. 2A, the second backside source/drain contact structure 80b and the power supply rail 86 may constitute a backside source/drain conductive line that may apply the operating voltage to the second source/drain region 34R.

A silicide layer 78 may be formed between the second backside source/drain contact structure 80b and the second source/drain region 34R. The silicide layer 78 formed on an end of the second backside contact structure 80b that contacts the second source/drain region 34R (e.g., that contacts the source/drain region 34R via the silicide layer 78), may be a compound of a metal component of the second backside source/drain contact structure 80b and a silicon component of the source/drain region 34R. The silicide layer 78 may be chemically stable and have low contact resistance compared to a metal-semiconductor junction. In FIG. 2A, for convenience of illustration, an upper surface of the silicide layer 78 and an upper surface of the insulating structure 74 are depicted as having the same plane, but a vertical level of the upper surface of the silicide layer 78 may be located above or below a vertical level of the upper surface of the insulating structure 74.

An electrical insulating layer 76 may be formed on a side wall of the end of the second backside contact structure 80b that contacts the second source/drain region 34R (e.g., that contacts the source/drain region 34R via the silicide layer 78). The electrical insulating layer 76 may be a layer in which a specific first material layer is converted into an electrical insulating layer by a specific insulation process. In one or more embodiments, the first material layer may include a semiconductor material layer. The electrical insulating layer 76 may provide an electrical insulation between semiconductor devices. An oxidation process may be performed to convert the semiconductor material layer into the electrical insulating layer 76, but embodiments are not limited thereto. In one or more embodiments, a nitridation process or an oxynitridation process may be performed to convert the semiconductor material layer into the electrical insulating layer 76. In one or more embodiments, the semiconductor material layer may include a silicon layer (e.g., a bulk silicon layer), and the electrical insulating layer 76 may include a silicon oxide layer. In one or more embodiments, the electrical insulating layer 76 may include a silicon nitride layer or a silicon oxynitride layer.

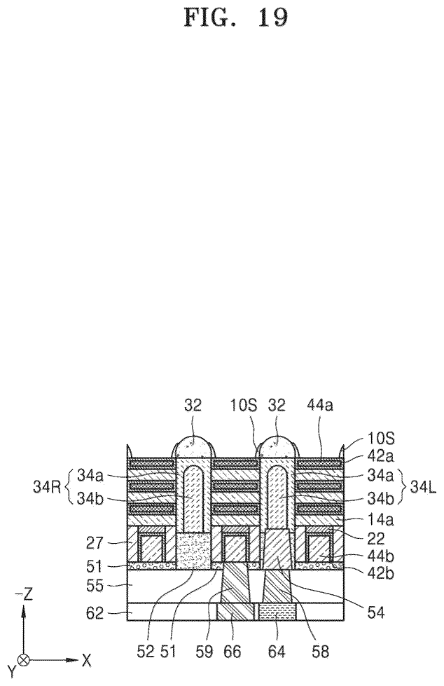

A semiconductor residue layer 10S, a residue of the semiconductor material layer, may be further formed on an outer side surface of the electrical insulating layer 76 that is formed on a side surface of the end of the second backside source/drain contact structure 80b that contacts the second source/drain region 34R (e.g., that contacts the source/drain region 34R via the silicide layer 78). The semiconductor residue layer 10S may be a portion of material of a substrate 10 that remains after the substrate 10 has not been fully removed, as described below with reference to FIG. 19. The semiconductor residue layer 10S may be the residue of the semiconductor material layer that is not converted to the electrical insulating layer 76 by the oxidation, nitridation, or oxynitridation process.

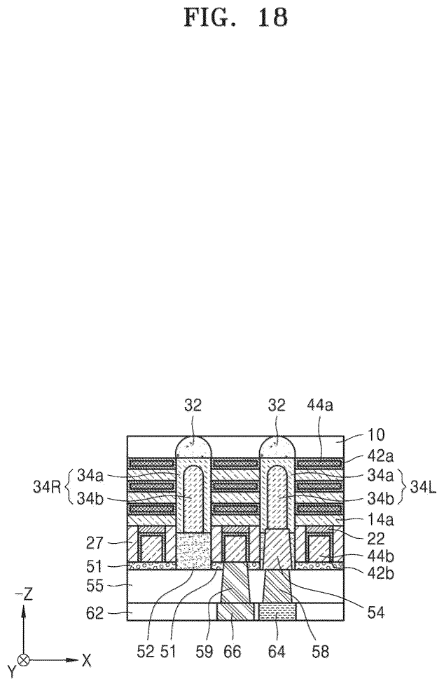

A protruding portion that protrudes downward from the upper surface of the insulating structure 74 may be formed under the first source/drain region 34L. The protruding portion may be a place holder layer 32. The place holder layer 32 may enable positions of the first and second backside source/drain contact structures 80a and 80b to be determined after positions of the first and source/drain regions 34L and 34R are identified during a removal process of the substrate 10 (see FIG. 18) in the manufacturing operations of the integrated circuit device 100a according to one or more embodiments. The place holder layer 32 may include an epitaxial-grown semiconductor layer. When a diameter of the second backside source/drain contact structure 80b in the first horizontal direction (X direction) is less than the diameter of the place holder layer 32 in the first horizontal direction, or when a position of a contact hole for forming the second backside source/drain contact structure 80b is misaligned with the position of the place holder layer 32, the residue of the place holder layer 32 may be at least partially around a side surface of the second backside source/drain contact structure 80b.

The semiconductor residue layer 10S may be formed along the perimeter of the side surface of the place holder layer 32 formed at a lower portion of the first source/drain region 34L. In one or more embodiments, the semiconductor residue layer 10S formed on the side surface of the place holder layer 32 that protrudes downward from the lower portion of the first source/drain region 34L, may be formed along the entire perimeter of the place holder layer 32. In one or more embodiments, the semiconductor residue layer 10S formed on the side surface of the place holder layer 32 formed at the lower portion of the second source/drain region 34R, may be formed at a portion of the perimeter of the place holder layer 32. In one or more embodiments, the semiconductor residue layer 10S may be formed in a spacer shape on the side wall of the electrical insulating layer 76. In addition, the semiconductor residue layer 10S may be formed in the spacer shape on the side wall of the place holder layer 32.

FIG. 2B is a cross-sectional view of an example integrated circuit device 100b taken along the line I-I′ of FIG. 1 according to one or more embodiments. Description of aspects the same as or similar to those described above may be omitted.

FIG. 2B differs from FIG. 2A in that both the first source/drain region 34L and the second source/drain region 34R may have the first and second backside source/drain contact structures 80a and 80b each electrically connected thereto.

Referring to FIG. 2B, a frontside source/drain contact structure that is electrically connected to the first source/drain region 34L may not be formed, and instead, the first backside source/drain contact structure 80a may be formed. The first backside source source/drain contact structure 80a formed under the first source/drain region 34L may be substantially the same as the second backside source/drain contact structure 80b formed under the second source/drain region 34R. In addition, the silicide layer 78, the electrical insulating layer 76, and the semiconductor residue layer 10S described in relation to the second backside source/drain contact structure 80b may also be formed with the same configuration as the first backside source/drain contact structure 80a.

In addition, the residues of the place holder layer 32 may be at least partially around the side surfaces of the first and second backside source/drain contact structures 80a and 80b.

FIG. 2C is a cross-sectional view of an example integrated circuit device 100c taken along the line I-I′ of FIG. 1 according to one or more embodiments. Description of aspects the same as or similar to those described above may be omitted.

FIG. 2C differs from FIG. 2A in that both the first source/drain region 34L and the second source/drain region 34R may have the first and second backside source/drain contact structures 80a and 80b each electrically connected thereto. In addition, an additional semiconductor residue layer 10R may be further formed between the first backside source/drain contact structure 80a and the second backside source/drain contact structure 80b. The additional semiconductor residue layer 10R may be a portion in which remains without being completely removed from the substrate 10, for example, during the manufacturing operation of the integrated circuit device shown in FIG. 19.

Referring to FIG. 2C, the additional semiconductor residue layer 10R may be formed along the surface of the insulating structure 74 between the first backside source/drain contact structure 80a and the second backside source/drain contact structure 80b. Thus, in one or more embodiments, the additional semiconductor residue layer 10R may be formed between the insulating structure 74 and the first gate structure GL1. For example, the additional semiconductor residue layer 10R may be formed continuously between the semiconductor residue layers 10S formed on the outer surfaces of the electrical insulating layers 76 that are formed along the side walls of the ends of the first and second backside sources/drain contact structures 80a and 80b. That is, the semiconductor residue layer 10R may be formed as between the sidewalls of ends of the first and second backside sources/drain contact structures 80a and 80b. In one or more embodiments, the additional semiconductor residue layer 10S may be formed discontinuously between the first and second backside sources/drain contact structures 80a and 80b. In FIG. 2C, the semiconductor residue layer 10S and the additional semiconductor residue layer 10R are depicted separately, but both may be portions of the substrate 10 that remain without being completely removed, for example, during the manufacturing operation of the integrated circuit device shown in FIG. 19.

In addition, the additional semiconductor residue layer 10R may be formed continuously or discontinuously between the place holder layer 32 and the second backside source/drain contact structure 80b in the integrated circuit device 100a shown in FIG. 2A.

FIG. 2D is a cross-sectional view of an example integrated circuit device 100d taken along the line I-I′ of FIG. 1 according to one or more embodiments. Description of aspects the same as or similar to those described above may be omitted.

FIG. 2D differs from FIG. 2A in that both the first source/drain region 34L and the second source/drain region 34R may have the first backside source/drain contact structures 80a and 80b each electrically connected thereto. In addition, the semiconductor residue layer 10S may not be formed on the side surface of the electrical insulating layer 76.

Referring to FIG. 2D, the semiconductor residue layer 10S may not be formed on the side surface of the electrical insulating layer 76. Thus, the semiconductor residue layer 10S has been completely converted into the electrical insulating layer 76. In addition, the residues of the place holder layer may be at least partially around the side surfaces of the first and second backside source/drain contact structures 80a and 80b. In addition, as shown in FIG. 2C, the additional semiconductor residue layer 10R may be formed continuously or discontinuously between the first and second backside source/drain contact structures 80a and 80b.

FIG. 3A is a cross-sectional view of an example integrated circuit device 100e taken along the line I-I′ of FIG. 1 according to one or more embodiments. FIG. 3A shows that the second backside source/drain contact structure 80b is electrically connected to the second source/drain region 34R, and the frontside source/drain contact structure is electrically connected to the first source/drain region 34L.

Compared to FIG. 2A, the integrated circuit device 100e is different in that the place holder layer may not be included under the first source/drain region 34L. Instead of including the place holder layer, the first source/drain region 34L may include a protruding portion that protrudes downwardly from the upper surface of the insulating structure 74, where the protruding portion may a portion of the first source/drain region 34L that extends downwardly from the upper surface of the insulating structure 74.

Accordingly, the semiconductor residue layer 10S may be formed along a side surface of the protruding portions of the first source/drain region 34L instead of the side surface of the place holder layer. In one or more embodiments, the semiconductor residue layer 10S formed on the side surface of the protruding portion that protrudes downwardly in a lower portion of the first source/drain region 34L, may be formed along the entire perimeter of the protruding portion. In one or more embodiments, the semiconductor residue layer 10S formed on the side surface of the protruding portion formed at the lower portion of the first source/drain region 34L, may be formed along a portion of the perimeter of the protruding portion.

FIG. 3B is a cross-sectional view of an example integrated circuit device 100f taken along the line I-I′ of FIG. 1 according to one or more embodiments. Description of aspects the same as or similar to those described above may be omitted.

FIG. 3B differs from FIG. 3A in that both the first source/drain region 34L and the second source/drain region 34R may have the first and second backside source/drain contact structures 80a and 80b each electrically connected thereto.

Referring to FIG. 3B, a frontside source/drain contact structure that is electrically connected to the first source/drain region 34L may not be formed, and instead, the first backside source/drain contact structure 80a may be formed. The first backside source source/drain contact structure 80a formed under the first source/drain region 34L may be substantially the same as the second backside source/drain contact structure 80b formed under the second source/drain region 34R. In addition, the silicide layer 78, the electrical insulating layer 76, and the semiconductor residue layer 10S described in relation to the second backside source/drain contact structure 80b may also be formed with the same configuration as the first backside source/drain contact structure 80a.

FIG. 3C is a cross-sectional view of an example integrated circuit device 100g taken along the line I-I′ of FIG. 1 according to one or more embodiments. Description of aspects the same as or similar to those described above may be omitted.

FIG. 3C differs from FIG. 3B in that the additional semiconductor residue layer 10R may be further formed between the first backside source/drain contact structure 80a and the second backside source/drain contact structure 80b.

Referring to FIG. 3C, the additional semiconductor residue layer 10R may be formed along the surface of the insulating structure 74 between the first backside source/drain contact structure 80a and the second backside source/drain contact structure 80b. In one or more embodiments, the additional semiconductor residue layer 10R may be formed continuously or discontinuously between the first and second backside source/drain contact structures 80a and 80b. In addition, the additional semiconductor residue layer 10R may be formed continuously or discontinuously between the protruding portion of the first source/drain region 34L and the second backside source/drain contact structure 80b in the integrated circuit device 100e shown in FIG. 3A.

FIG. 3D is a cross-sectional view of an example integrated circuit device 100h taken along the line I-I′ of FIG. 1 according to one or more embodiments. Description of aspects the same as or similar to those described above may be omitted.

FIG. 3D differs from FIG. 3A in that both the first source/drain region 34L and the second source/drain region 34R may have the first and second backside source/drain contact structure 80a and 80b each electrically connected thereto. Referring to FIG. 3D, the semiconductor residue layer 10S may not be formed on the side surface of the electrical insulating layer 76. Thus, the semiconductor residue layer 10S has been completely converted into the electrical insulating layer 76.

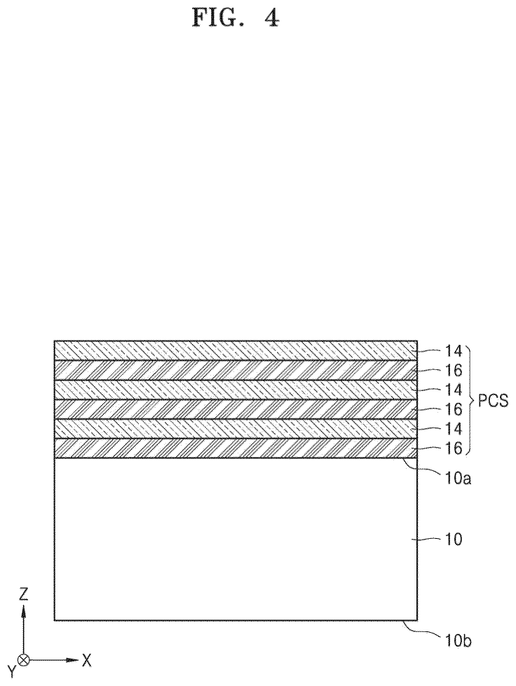

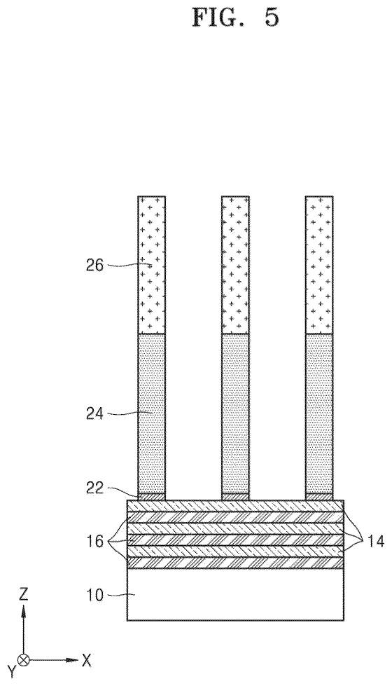

FIGS. 4 to 23 are cross-sectional views sequentially illustrating of manufacturing an integrated circuit device according to one or more embodiments. The cross-sectional views of FIGS. 4 to 23 are cross-sectional views taken along the I-I′ line of FIG. 1. For example, FIGS. 4 to 23 represents the operations of manufacturing the integrated circuit device 100a shown in FIG. 2A.

The integrated circuit device 100 according to one or more embodiments may constitute a logical cell comprising an MBCFET device. However, embodiments are not limited thereto, and the integrated circuit device 100 may include a planar FET device, a gate-all-around type FET device, a finFET device, or a FET device based on a two-dimensional material such as a MoS₂ semiconductor gate electrode.

Referring to FIG. 4, a preliminary channel stack (PCS) may be formed on a substrate 10. The PCS may include a plurality of preliminary channel layers 14 and a plurality of preliminary sacrificial layers 16. It is illustrated that three preliminary sacrificial layers 16 and three preliminary channel layers 14 are formed on the substrate 10, but embodiments are not limited thereto.

The substrate 10 may include a first surface 10a on a frontside in the Z direction and a second surface 10b on the backside corresponding to the first surface 10a. In one or more embodiments, the substrate 10 may include a group IV semiconductor such as Si or Ge, an group IV-IV compound semiconductor such as SiGe or SiC, or a group III-V compound semiconductors such as GaAs, InAs, or InP. However, as described below, the substrate 10 may be a kind of sacrificial substrate because it may be completely removed in a subsequent process.

The substrate 10 may not be completely removed in the subsequent process and may remain as a residue on a surface of a gate structure. The substrate 10 may be the origin of the semiconductor residue layer 10S described in FIGS. 2A to 3C. The substrate 10 may include various kinds of materials in which all or at least a portion of the semiconductor residue layer 10S may be converted to the electrical insulating layer by an insulating layering process. In one or more embodiments, the substrate 10 may include a bulk silicon substrate, but embodiments are not limited thereto.

The plurality of preliminary sacrificial layers 16 and the plurality of preliminary channel layers 14 that constitute the PCS may be formed by an epitaxial growth method. The plurality of preliminary sacrificial layers 16 and the plurality of preliminary channel layers 14 may include different semiconductor materials.

In one or more embodiments, the preliminary sacrificial layer 16 may include SiGe, and the preliminary channel layer 14 may include of Si, but embodiments are not limited thereto. The plurality of preliminary sacrificial layers 16 and the plurality of preliminary channel layers 14 may all be formed with the same thickness, but embodiments are not limited thereto.

Referring to FIG. 5, a preliminary mask pattern may be formed on the PCS. The preliminary mask pattern may be formed by sequentially forming an insulating layer 22, a dummy polysilicon layer 24, and a capping insulating layer 26 on the preliminary channel layer 14 formed at a top of the PCS, and then etching them using an etching mask to form a plurality of patterns while maintaining a certain interval in the first horizontal direction (X direction). The insulating layer 22 may constitute a portion of the second gate insulating layer of the second gate structure GL2 as described above with respect to FIG. 3A. The dummy polysilicon layer 24 may include a layer in which impurities doped. The capping insulating layer 26 may include a silicon nitride layer.

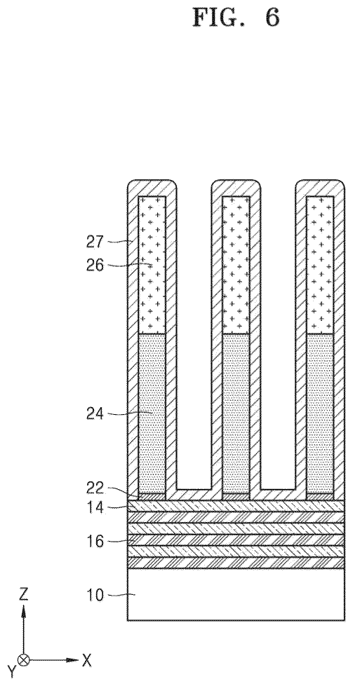

Referring to FIG. 6, a spacer insulating layer 27 may be formed on an entire surface of the substrate 10. The spacer insulating layer 27 may be formed with a substantially uniform thickness on exposed surfaces of the insulating layer 22, the dummy polysilicon layer 24, the capping insulating layer 26, and the preliminary channel layer 14. The spacer insulating layer 27 may include a silicon oxide layer.

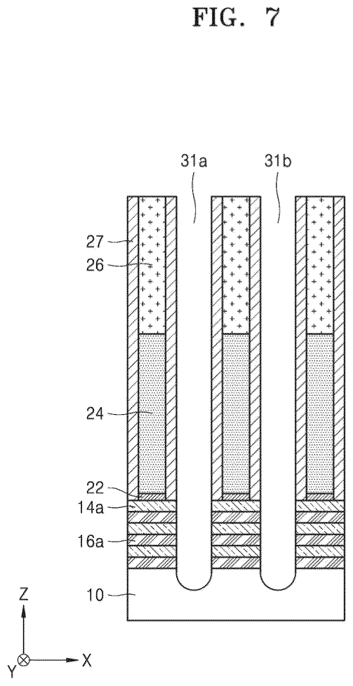

Referring to FIG. 7, an anisotropic etching process may be performed on the spacer insulating layer 27 to form a spacer insulating layer 27 on side walls of the preliminary mask pattern, thereby forming a mask pattern. The mask pattern may include the insulating layer 22, the dummy polysilicon layer 24, the capping insulating layer 26, and the spacer insulating layer 27. A first opening portion 31a and a second opening portion 31b may be defined in the mask pattern. An etching process may be performed using the mask pattern in which the first opening portion 31a and the second opening portion 31b are formed as an etching mask, thereby forming a first preliminary source/drain region at a bottom of the first opening portion 31a and a second preliminary source/drain region at the bottom of the second opening portion 31b, respectively. The etching process using the mask pattern with the first opening portion 31a and the second opening portion 31b as the etching mask may be performed until the first and second opening portions extend to a predetermined depth below the first surface 10a of the substrate 10 while penetrating the PCS.

By the etching process, portions of the PCS may be removed, so that the PCS may be separated along the X direction. According to the separation of the PCS, the preliminary sacrificial layer 16 may be referred to as a sacrificial layer 16a and the preliminary channel layer 14 may be referred to as a channel layer 14a.

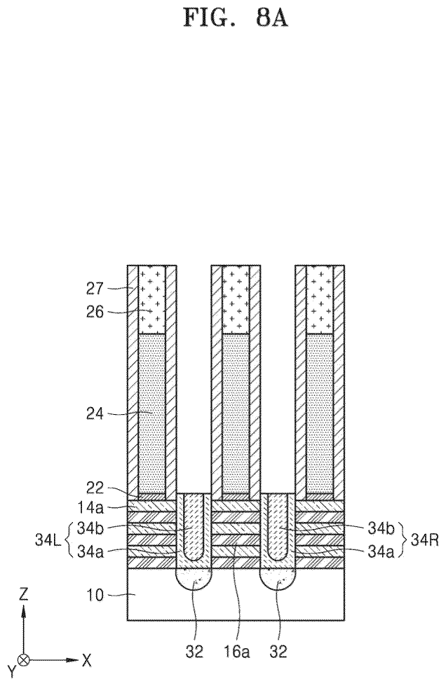

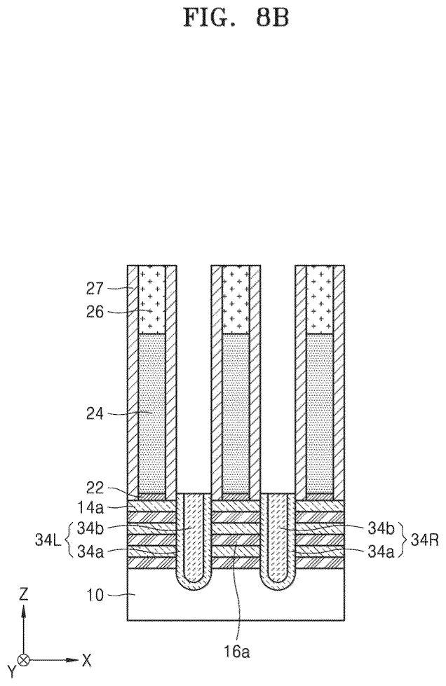

Referring to FIG. 8A, a first place holder layer 32 (e.g., the place holder layer 32 shown on the left side of FIG. 8A) and a second place holder layer 32 (e.g., the place holder layer 32 shown on the right side of FIG. 8A) may be respectively formed on the exposed substrates 10 of the first preliminary source/drain region and the second preliminary source/drain region. The place holder layer 32 may be an epitaxial layer formed by selectively epitaxial growth of a semiconductor material in the exposed portion of the substrate 10. In one or more embodiments, the place holder layer 32 may include an epitaxial Si layer, an epitaxial SiC layer, or an epitaxial SiGe layer.

Subsequently, the first and second source/drain regions 34L and 34R may be formed by selectively growing the semiconductor material doped with impurities on the epitaxial grown place holder layer 32. The first and second source/drain regions 34L and 34R may each be a single source/drain region structure having the same impurity concentration. In some embodiments, the source/drain region 34L and 34R may include, for example, the inner source/drain region 34b arranged in the inner side thereof and the outer source/drain region 34a surrounding the inner source/drain region 34b. The inner source/drain region 34b and the outer source/drain region 34a may be distinguished from each other by the difference in impurity concentration. In one or more embodiments, the impurity concentration of the inner source/drain region 34b may be greater than the impurity concentration of the outer source/drain region 34a, but is not limited thereto.

In one or more embodiments, the impurity may include boron (B), arsenic (AS), or phosphorus (P). The first and second source/drain regions 34L and 34R may include a doped SiGe layer, a doped Ge layer, a doped SiC layer, or a doped InGaAs layer, but embodiments are not limited thereto.

In the case of a p-type metal-oxide-semiconductor (MOS) (PMOS) transistor and an n-type MOS (NMOS) transistor, the place holder layer 32 and the first and second source/drain regions 34L and 34R may include different materials from each other due to their operating characteristics. A process of forming the place holder layer and the source/drain regions in a region where the PMOS transistor is formed and a process of forming the place holder layer and the source/drain regions in a region where the NMOS transistor is formed, may be performed in different operations.

Referring to FIG. 8B, the place holder layer may not be formed at the bottom of the first and second source/drain regions 34L and 34R. In one or more embodiments, instead of forming the place holder layer, lower portions of the first and second source/drain regions 34L and 34R may protrude downward from the first surface 10a, which is the upper surface of the substrate 10.

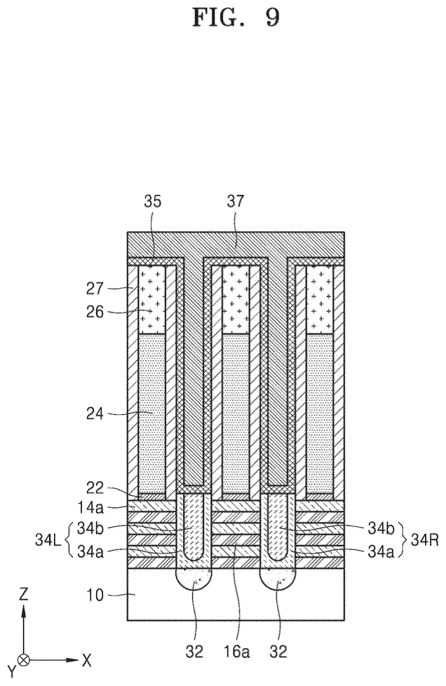

Referring to FIG. 9, an insulating layer may be formed on the entire surface of the substrate where the first and second source/drain regions 34L and 34R are formed, thereby filling the first opening portion 31a and the second opening portion 31b (see FIG. 7). The insulating layer may include a liner insulating layer 35 and a filling insulating layer 37. In one or more embodiments, the liner insulating layer 35 may include a silicon nitride layer, and the filling insulating layer 37 may include a silicon oxide layer. In one or more embodiments, the filling insulating layer 37 may include a polysilazane layer called a tonen silazene (TOSZ) layer, but embodiments are not limited thereto.

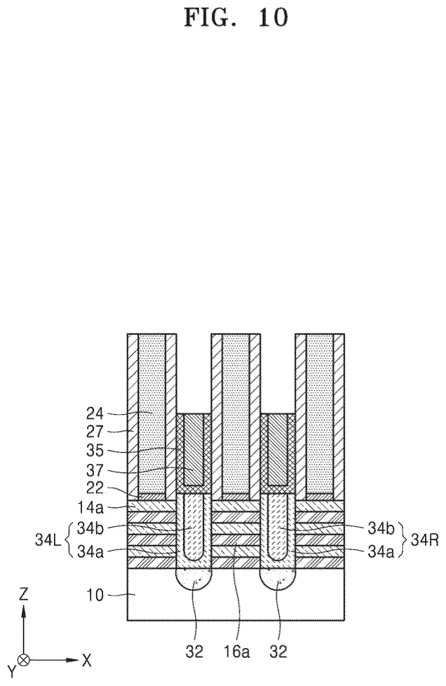

Referring to FIG. 10, an etching process may be performed on the result of FIG. 9 so that a portion of the liner insulating layer 35 and a portion of the filling insulating layer 37 remain over the first source/drain region 34L and the second source/drain region 34R. The capping insulating layer 26 may be removed from the mask pattern for defining the first preliminary source/drain region and the second preliminary source/drain region, thereby exposing the dummy polysilicon layer 24.

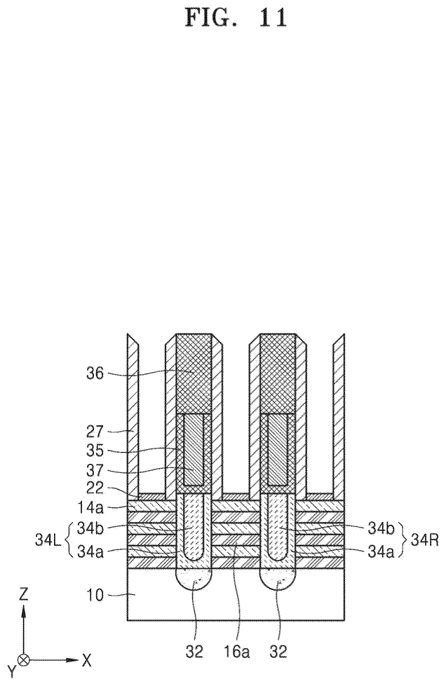

Referring to FIG. 11, a mask insulating layer 36 for removing the dummy polysilicon layer 24 may be formed on the liner insulating layer 35 and the filling insulating layer 37 that remain over the first source/drain region 34L and the second source/drain region 34R. In one or more embodiments, the mask insulating layer 36 may include a silicon nitride layer. The mask insulating layer 36 may be obtained by forming a material for the mask insulating layer 36 on the entire surface of the result of FIG. 10, completely filling a space over the liner insulating layer 35 and the filling insulating layer 37 that remain over the first source/drain region 34L and the second source/drain region 34R, and then the method may include performing an etching process until the dummy polysilicon layer 24 is exposed.

Referring to FIG. 11, only the exposed dummy polysilicon layer 24 may be selectively removed. The insulating layer 22 under the dummy polysilicon layer 24 may remain or be removed.

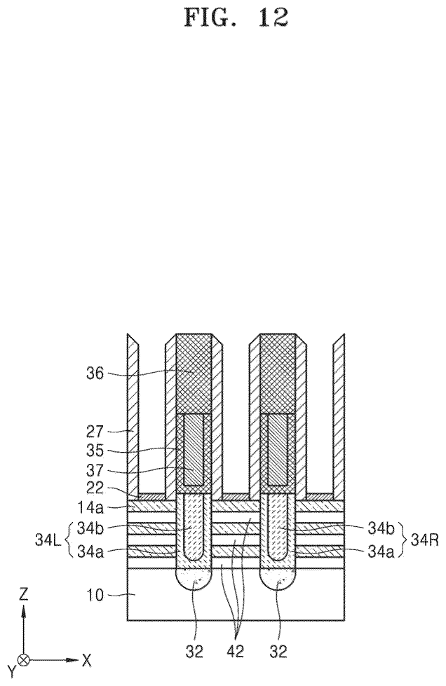

Referring to FIG. 12, the plurality of sacrificial layers 16a may be selectively removed from the PCS (see FIG. 4). A process of removing the plurality of sacrificial layers 16a may be performed through a radical-assisted SiGe etching (RASE) process. Portions from which the plurality of sacrificial layers 16a are removed in the PCS may produce a plurality of spaces 42. Surfaces of the channel layers 14a may be exposed to the spaces 42.

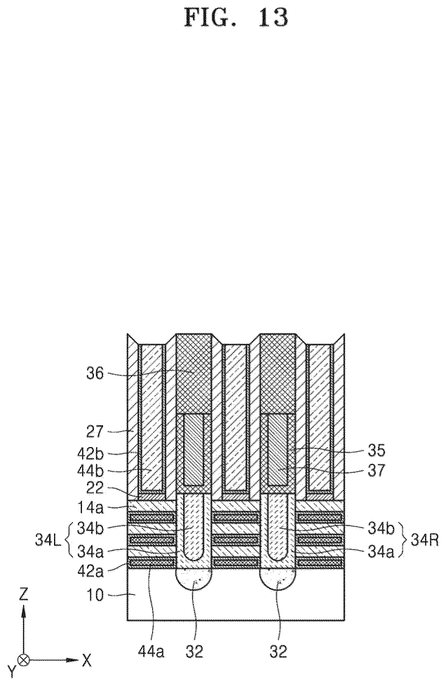

Referring to FIG. 13, a first gate insulating layer 42a may be thinly formed on the surfaces of the channel layers 14a exposed to the spaces 42. The first gate insulating layer 42a may not fully fill the spaces 42 while leaving second spaces less than the first spaces 42.

The first gate insulating layer 42a may include a high-k dielectric film. The high-k dielectric film may include a material with a higher dielectric constant than a silicon oxide film. For example, the high-k dielectric film may have a dielectric constant of about 10 to about 25. The high-k dielectric film may include a material such as hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, and combinations thereof, but the material constituting the high-k dielectric film is not limited thereto.

The high-k dielectric film may be formed by an atomic layer deposition (ALD) process, a chemical vapor deposition (CVD) process, or a physical vapor deposition (PVD) process. The high-k dielectric film may have a thickness of about 10 to about 40 angstroms, but embodiments are not limited thereto.

A second gate insulating layer 42b may be formed on the exposed surfaces of the spacer insulating layer 27 and the insulating layer 22 at the same time as the formation of the first gate insulating layer 42a. The first gate insulating layer 42a and the second gate insulating layer 42b may be formed through the same deposition process and may include the same material.

Referring again to FIG. 13, a replacement metal gate (RMG) process may be performed on the first gate insulating layer 42a to form a first gate electrode layer 44a, thereby completely filling the second spaces. A second gate electrode layer 44b may be formed simultaneously on the second gate insulating layer 42b.

The first gate electrode layer 44a and the second gate electrode layer 44b may include a metal layer or a metal nitride layer. In one or more embodiments, the first gate electrode layer 44a and the second gate electrode layer 44b may include at least one of Ti, W, Al, Ru, Nb, Mo, Hf, Ni, Co, Pt, Yb, Dy, Er, Pd, TiN, TaN, and combinations thereof.

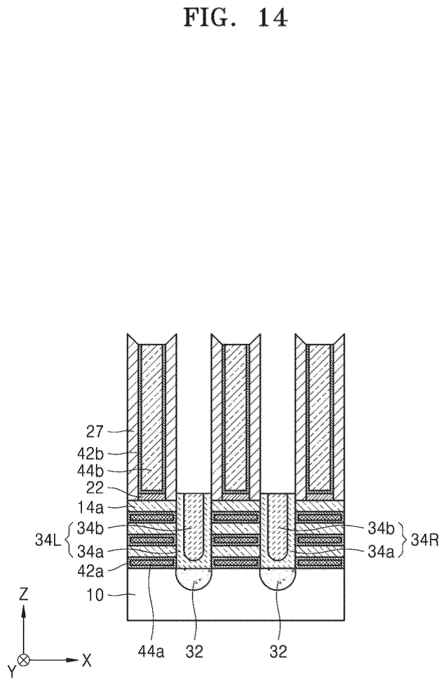

Referring to FIG. 14, the liner insulating layer 35, the filling insulating layer 37, and the mask insulating layer 36 may be removed so as to expose the first and second sources/drain regions 34L and 34R.

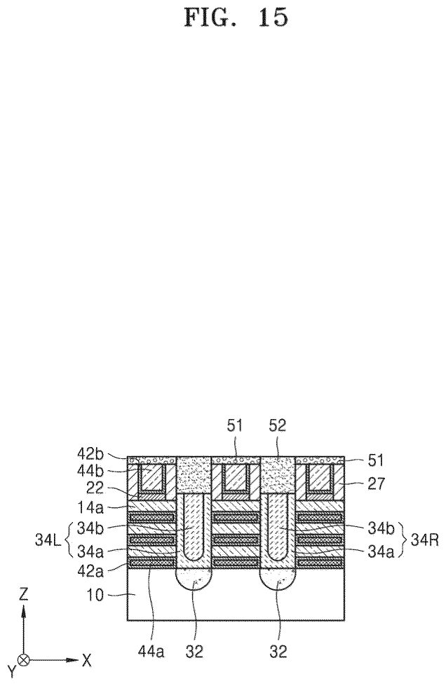

Referring to FIG. 15, after forming the second gate structure GL2, a first interlayer insulating layer 52 may be formed on the first and second source/drain regions 34L and 34R, a gate capping layer 51 may be formed on the second gate structure GL2, and then, a surface planarization process may be performed.

Referring to FIGS. 14 and 15 together, a chemical mechanical polishing (CMP) process may be performed on the entire surface of the result of FIG. 13 without removing the liner insulating layer 35, the filling insulating layer 37, and the mask insulating layer 36, thereby forming the second gate electrode layer 44b with a desired height, and then the liner insulating layer 35, the filling insulating layer 37, and the mask insulating layer 36 may be removed. Next, the first interlayer insulating layer 52 may be filled in portions where the liner insulating layer 35, the filling insulating layer 37, and the mask insulating layer 36 are removed (i.e., on the first and second source/drain regions 34L and 34R), and the gate capping layer 51 may be formed on the second gate electrode layer 44b, the second gate insulating layer 42b, and the spacer insulating layer 27 that constitute the second gate structure GL2, and then the surface planarization process may be performed. In one or more embodiments, the first interlayer insulating layer 52 may include a silicon oxide layer, and the gate capping layer 51 may include a material having an etching selectivity with respect to the first interlayer insulating layer 52. For example, the gate capping layer 51 may include a silicon nitride layer, a silicon oxynitride layer, a silicon oxycarbide layer, or a silicon oxycarbonitride layer.

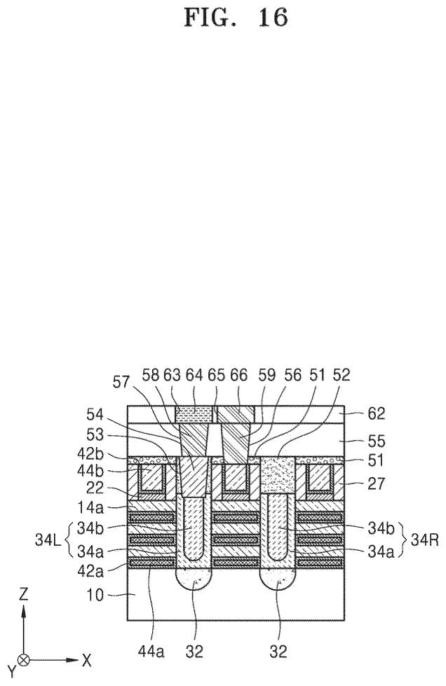

Referring to FIG. 16, a first contact hole 53 for exposing a first source/drain region 34L may be formed by removing a portion of the first interlayer insulating layer 52, and the first contact hole 53 may be filled to form a first contact plug 54. Next, after forming a second interlayer insulating layer 55 on the first interlayer insulating layer 52 and the gate capping layer 51, a second contact hole 57 may be formed by removing a portion of the second interlayer insulating layer 55, and then the second contact hole 57 may be filled to form a first via plug 58.

Next, after forming a third interlayer insulating layer 62 on the second interlayer insulating layer 55, a third contact hole 63 may be formed by removing a portion of the third interlayer insulating layer 62, and then the third contact hole 63 may be filled to form a source/drain connection wiring layer 64. The first contact plug 54, the first via plug 58, and the source/drain connection wiring layer 64 may constitute a first conductive line that may apply the operating voltage to the first source/drain region 34L. The first contact plug 54 and the first via plug 58 may be referred to as a frontside source/drain contact structure.

After forming a fourth contact hole 56 that penetrates the gate capping layer 51 and the second interlayer insulating layer 55 on the second gate electrode layer 44b, the fourth contact hole 56 may be filled to form a second contact plug 59. Next, after forming a fifth contact hole 65 that penetrates the third interlayer insulating layer 62 and exposes the second contact plug 59, the fifth contact hole 65 may be filled to form a gate connection wiring layer 66. The second contact plug 59 and the gate connection wiring layer 66 may constitute a second conductive line that may apply the operating voltage to the gate electrode layers 44a and 44b of the first and second gate structures GL1 and GL2. The second contact plug 59 may be referred to as a frontside gate contact structure.

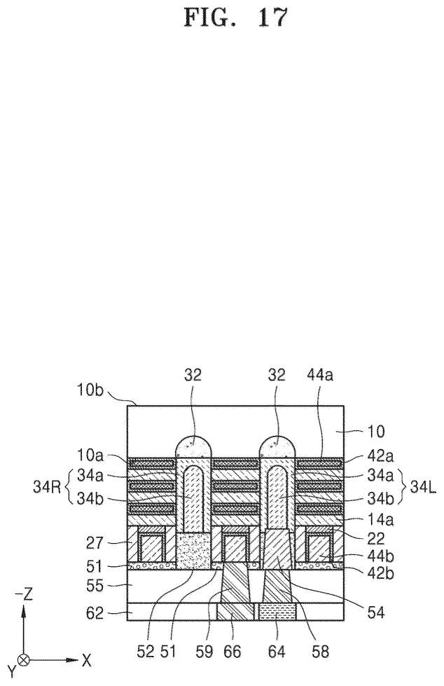

Referring to FIG. 17, a structure of FIG. 16 may be turned over, and then the manufacturing process of the integrated circuit device 100a may be performed.

Referring to FIG. 18, a backside etching process may be performed on the substrate 10 to partially etch and remove a portion of the substrate 10 until the place holder layer 32 is exposed. The backside etching process may be performed on the substrate 10 by a chemical polishing process.

Referring to FIG. 19, an etching process may be further performed on the substrate 10 until the gate insulating layer 42a of the first gate structure GL1 is exposed, thereby removing the remaining substrate 10. The etching process may be performed by a wet or a dry process. The place holder layer 32 and the first gate insulating layer 42a may remain without being etched because of etching selectivity against the substrate 10, and the substrate 10 may not be completely removed from side walls of the place holder layers 32 but may remain in the form of a stringer or a facet. A residue of the substrate 10 remaining on the side walls of the place holder layer 32 may be referred to as a substrate residue layer or a semiconductor residue layer 10S. For example, when the substrate 10 is a bulk silicon substrate, a silicon residue may likely form a leakage path between adjacent gate structures, source/drain regions, or backside source/drain contact structures.

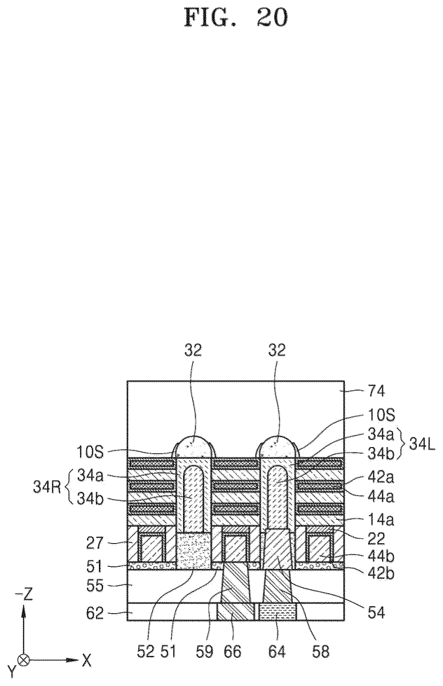

Referring to FIG. 20, an insulating structure 74 may be formed on the result of FIG. 19 to completely cover the exposed place holder layer 32. In one or more embodiments, the insulating structure 74 may include an oxide layer, for example a silicon oxide layer, but embodiments are not limited thereto.

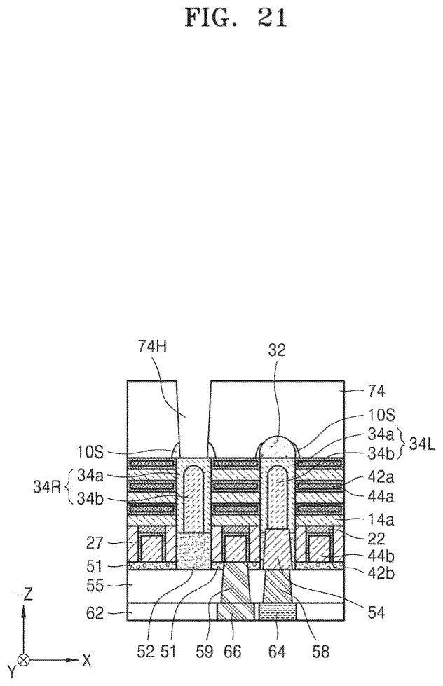

Referring to FIG. 21, a sixth contact hole 74H may be formed by etching a portion of the insulating structure 74 to expose at least a portion of the second source/drain region 34R. The place holder layer 32 that contacts the second source/drain region 34R may be also removed. Depending on the position where the sixth contact hole 74H is formed in the second place holder layer 32, a portion of the place holder layer 32 may not be completely removed and may remain.

The semiconductor residue layer 10S and a portion of the second source/drain region 34R may be exposed to the sixth contact hole 74H.

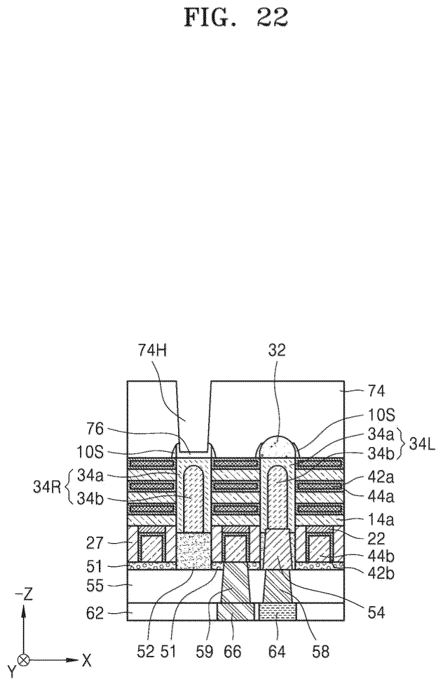

Referring to FIG. 22, an insulation process that may convert the semiconductor residue layer 10S into an electrical insulating layer may be performed on the result of FIG. 21. The insulation process may be an oxidation process, but embodiments are not limited thereto. For example, when the semiconductor residue layer 10S is a residue of the bulk silicon, the semiconductor residue layer 10S may be converted into a silicon oxide layer, which is an electrical insulating layer 76. The semiconductor residue layer 10S may be converted entirely into the electrical insulating layer 76 depending on conditions of the oxidation process. In one or more embodiments, only a portion of the semiconductor residue layer 10S may be converted into the electrical insulating layer 76. FIG. 22 shows that only the portion of the semiconductor residue layer 10S is converted into the electrical insulating layer 76. In this case, a portion of the semiconductor residue layer 10S may remain outside of the electrical insulating layer 76. The remaining semiconductor residue layer 10S may have a spacer shape along the side perimeter of the electrical insulating layer 76, and may remain entirely or partially along the side perimeter thereof.

The electrical insulating layer 76 may be formed on the exposed surface of the second source/drain region 34R. The electrical insulating layer 76 may be formed continuously along an inner circumferential surface and a bottom surface of a lower portion of the sixth contact hole 74H.

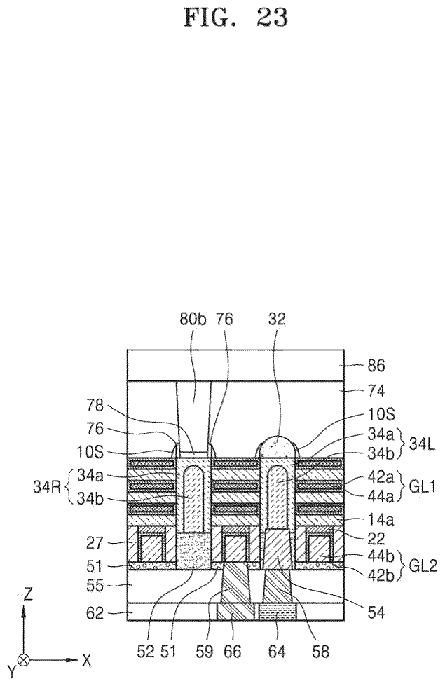

Referring to FIG. 23, after removing the electrical insulating layer 76 formed on the bottom surface of the sixth contact hole 74H (that is, the electrical insulating layer 76 formed on the exposed surface of the second source/drain region 34R), the sixth contact hole 74H may be filled with a conductive material such as a metal material, to form a second backside source/drain contact structure 80b. Silicidation between the second source/drain region 34R and the metal material of the second backside source/drain contact structure 80b may progress, so that a silicide layer 78 may be formed between the second source/drain region 34R and the second backside source/drain contact structure 80b. In one or more embodiments, the second backside source/drain contact structure 80b may include at least one of W, Co, Mo, Ni, Ru, Cu, Al, or alloys thereof, but embodiments are not limited thereto. The second backside source/drain contact structure 80b may further include a conductive barrier layer that contacts the insulating structure 74 along a side wall of the sixth contact hole 74H. The conductive barrier layer may include at least one of Ru, Ti, TiN, Ta, TaN, W, TiSiN, TiSi, or WSi.

Next, a power supply rail 86 may be formed on a rear side of the insulating structure 74 in which the second backside source/drain contact structure 80b is formed. The power supply rail 86 may be electrically connected to the second source/drain region 34R through the second backside source/drain contact structure 80b.

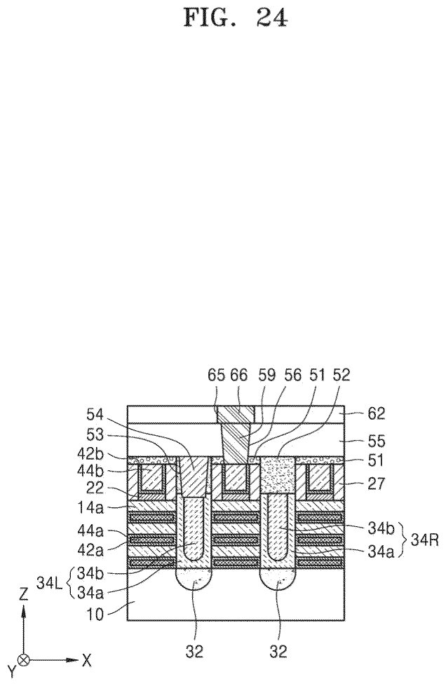

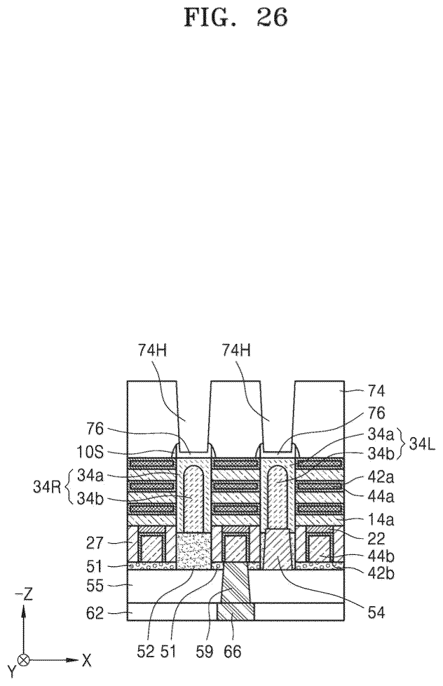

FIGS. 24 to 27 are cross-sectional views sequentially illustrating operations of manufacturing an integrated circuit device according to one or more embodiments. The cross-sectional views of FIGS. 24 to 27 are cross-sectional views taken along the I-I′ line of FIG. 1. For example, FIGS. 24 to 27 represents the operations of manufacturing the integrated circuit device 100b shown in FIG. 2B. Description of aspects the same as or similar to those described above may be omitted.

Referring to FIG. 24, after forming the second gate structure GL2 in the operation of FIG. 15, the gate capping layer 51 and the first interlayer insulating layer 52 may be formed and then the surface planarization process may be performed. For example, the first frontside source/drain contact structure may not be formed on the first contact plug 54. However, after forming the fourth contact hole 56 that penetrates the gate capping layer 51 and the second interlayer insulating layer 55 on the second gate electrode layer 44b, the fourth contact hole 56 may be filled to form the second contact plug 59. Next, after forming the fifth contact hole 65 that penetrates the third interlayer insulating layer 62 and exposes the second contact plug 59, the fifth contact hole 65 may be filled to form the gate connection wiring layer 66. The second contact plug 59 and the gate connection wiring layer 66 may constitute the second conductive line that may apply the operating voltage to the gate electrode layers 44a and 44b of the first and second gate structures GL1 and GL2. The second contact plug 59 may be referred to as the frontside gate contact structure.

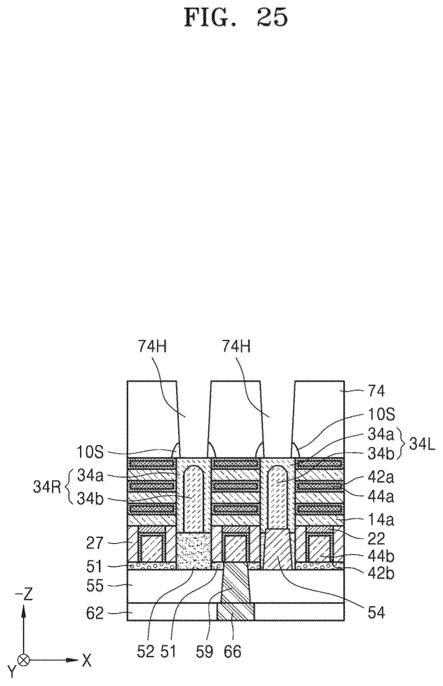

Referring to FIGS. 25 to 27, a structure of FIG. 24 may be turned over, and then the manufacturing process of the integrated circuit device 100b may be performed. For example, the operations of FIGS. 17 to 23 may be performed for the first source/drain region 34L in the same manner as in the second source/drain region 34R. As a result, as shown in FIG. 2B, the first and second backside source/drain contact structures 80a and 80b may be formed in the rear side of the integrated circuit device 100b.

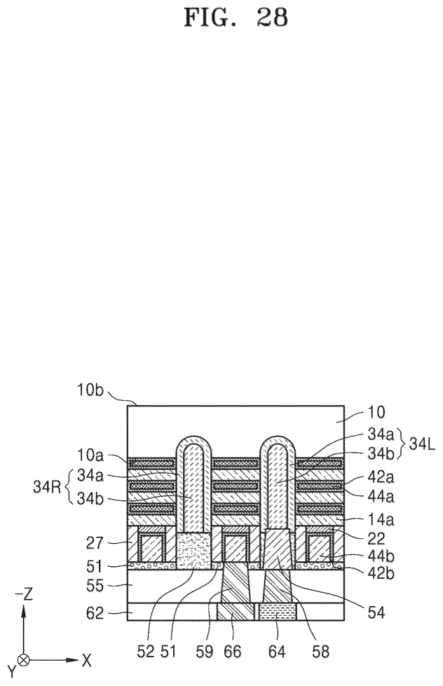

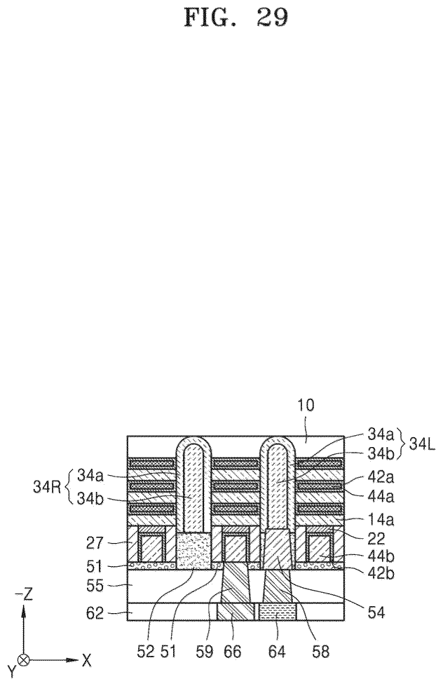

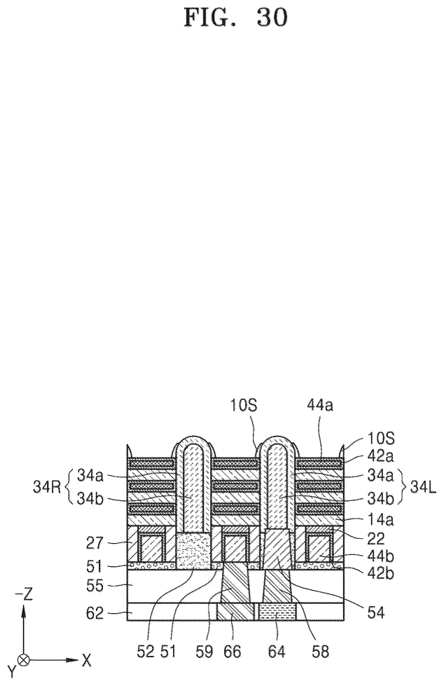

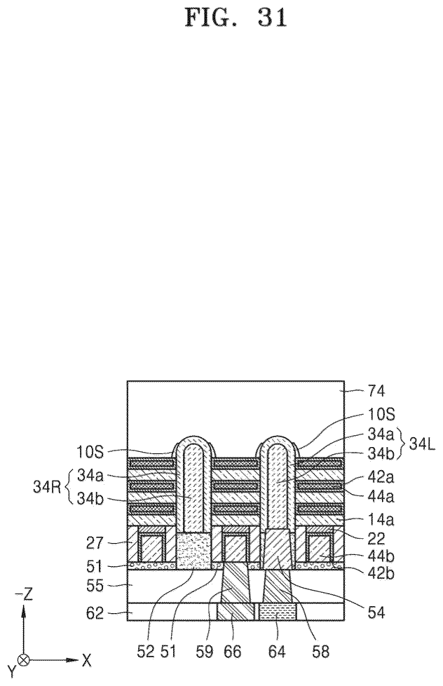

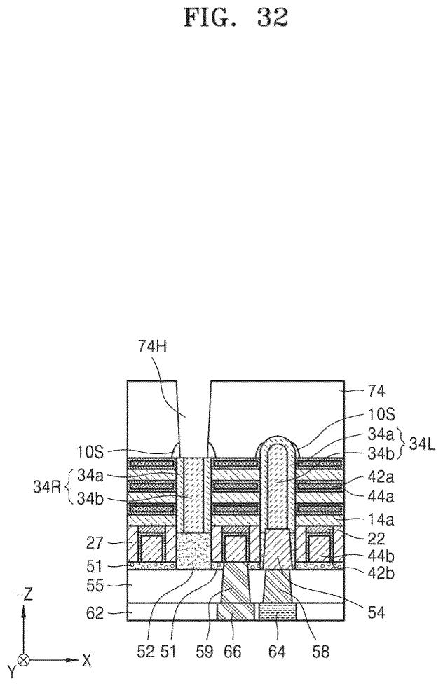

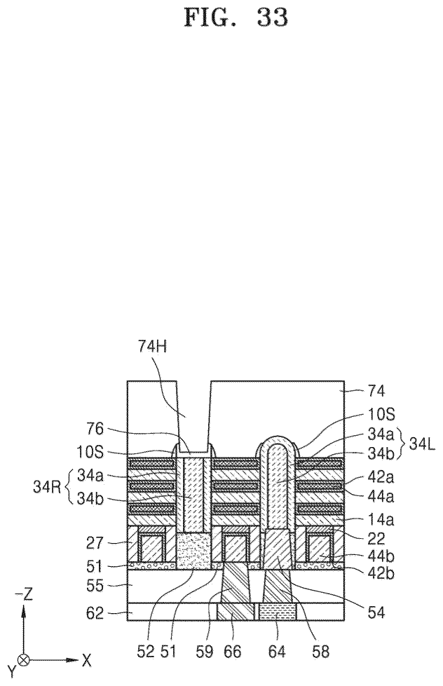

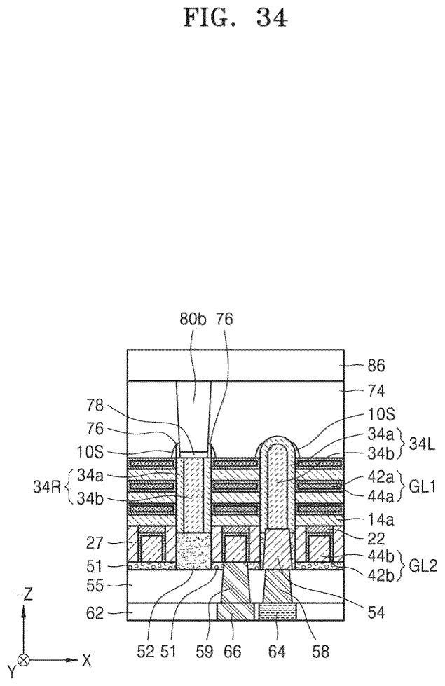

FIGS. 28 to 34 are cross-sectional views sequentially illustrating operations of manufacturing an integrated circuit device according to one or more embodiments. The cross-sectional views of FIGS. 28 to 34 are cross-sectional views taken along the I-I′ line of FIG. 1. For example, FIGS. 28 to 34 represents the steps of manufacturing the integrated circuit device 100e shown in FIG. 3A. Description of aspects the same as or similar to those described above may be omitted.

Referring to FIGS. 28 to 34, an embodiment is described in which a place holder layer is not formed at lower portions of the first and second source/drain regions 34L and 34R. That is, after forming the protruding portion in which the first and second source/drain regions 34L and 34R protrude downward from the first surface 10a of the substrate 10, the semiconductor residue layer 10S may be formed on the side walls of the protruding portion and all or part of the semiconductor residue layer 10S may be converted into the electrical insulating layer 76.

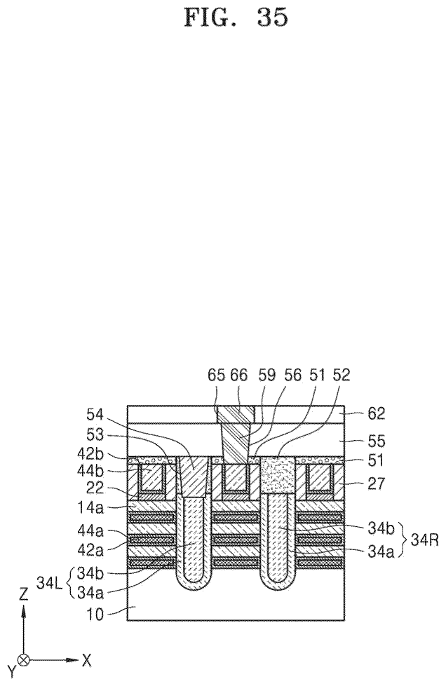

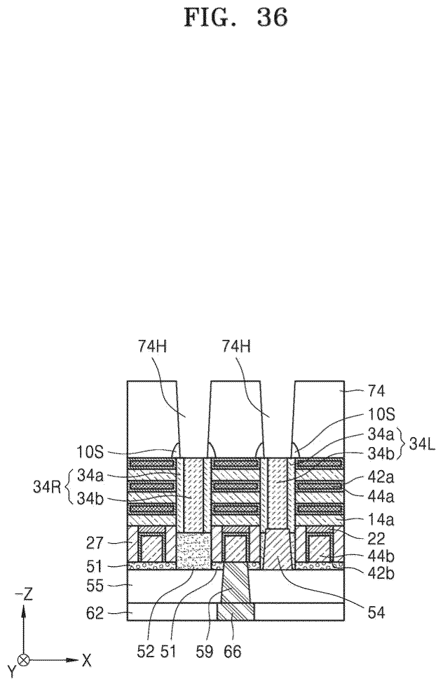

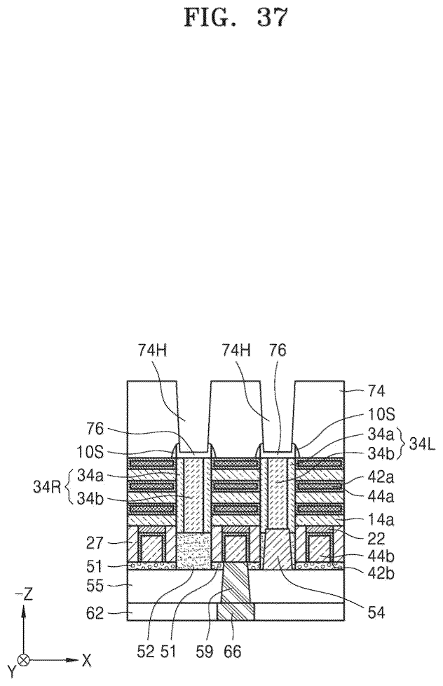

FIGS. 35 to 38 are cross-sectional views sequentially illustrating operations of manufacturing an integrated circuit device according to one or more embodiments. For example, FIGS. 35 to 38 represents the steps of manufacturing the integrated circuit device 100f shown in FIG. 3B. Description of aspects the same as or similar to those described above may be omitted.

Referring to FIGS. 35 to 38, place holder layers may not be formed at the lower portions of the first and second source/drain region 34L and 34R, and the steps of FIGS. 17 to 23 may be for the first source/drain region 34L in the same manner as for the second source/drain region 34R. As a result, as shown in FIG. 3B, the first and second backside source/drain contact structures 80a and 80b may be formed in the rear side of the integrated circuit device 100f.

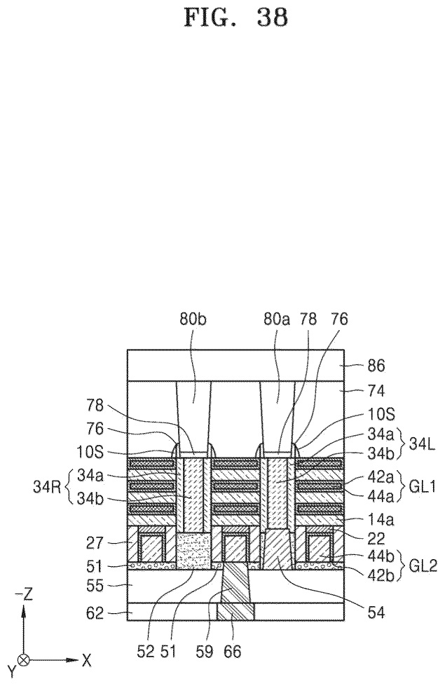

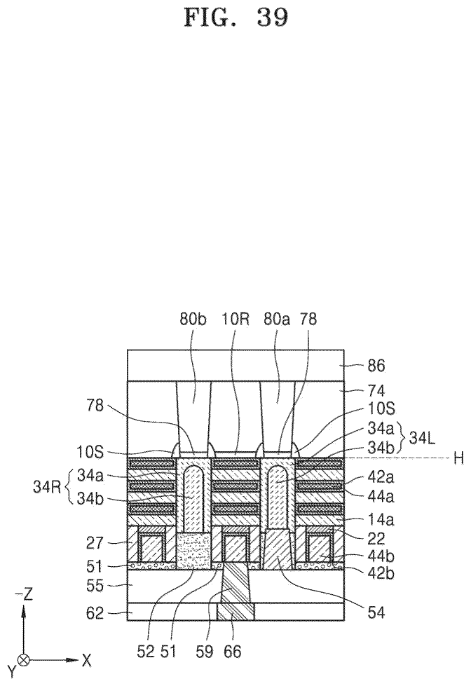

FIG. 39 is a cross-sectional view illustrating an integrated circuit device corresponding to FIG. 38, according to one or more embodiments.

Referring to FIG. 39, a relatively thick additional semiconductor residue layer 10R remains between the first and second source/drain regions 34L and 34R. The additional semiconductor residue layer 10R may be generated when the substrate 10 is not sufficiently removed during the backside etching process on the substrate 10 due to dispersion of etching process conditions. When the backside etching process on the substrate 10 progresses excessively, there may be a problem that the gate structure may be eroded. The additional semiconductor residue layer 10R remaining between the first and second source/drain regions 34L and 34R may become a passage of leakage current between the first and second source/drain regions 34L and 34R. Therefore, the additional semiconductor residue layer 10R may become a factor that distorts the operation of the integrated circuit device to decrease the reliability of the operation.

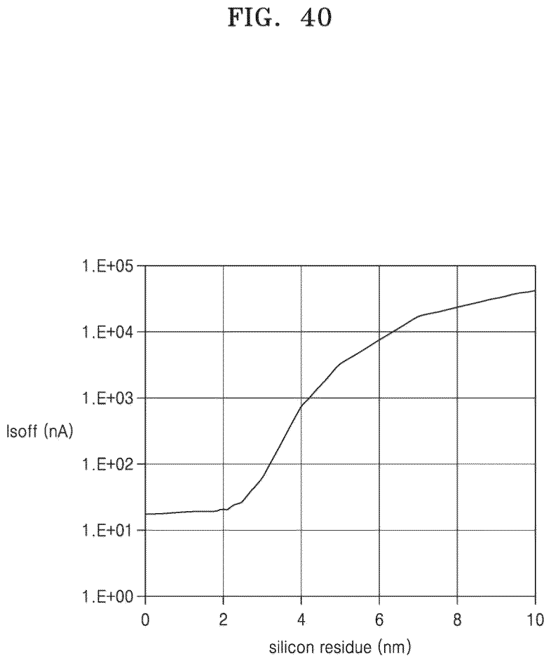

FIG. 40 is a graph showing a simulation of the magnitude of leakage current depending on the thickness of silicon residue remaining after a removal process of a bulk substrate according to one or more embodiments. For example, in the integrated circuit device of FIG. 39, it can be seen that when a thickness of the semiconductor residue layer 10R (for example, silicone residue) which remains relatively thickly between the first and second source/drain regions 34L and 34R is 2 nm or more, the magnitude of leakage current increases rapidly. Therefore, it can be seen that when the thickness of the silicon residue becomes, for example, 2 nm or more, the operational performance of the integrated circuit device deteriorates rapidly.

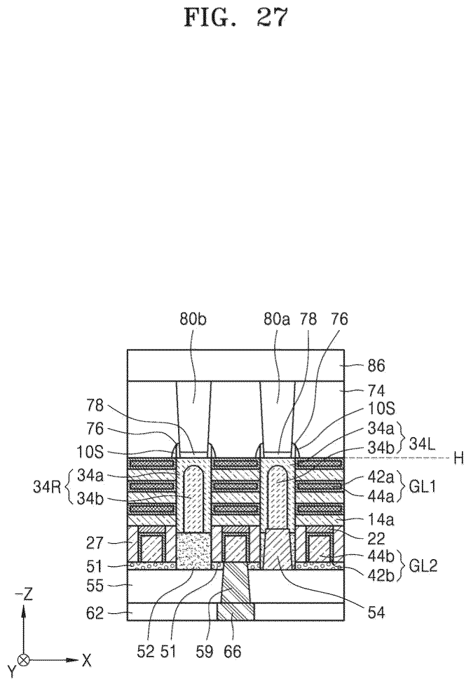

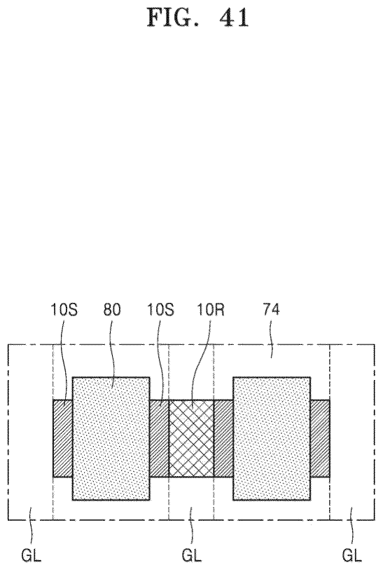

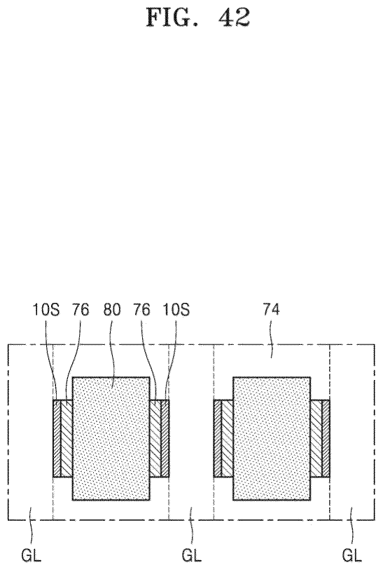

FIG. 41 is a bottom plan view taken at “H” level of FIG. 39 according to one or more embodiments. FIG. 42 is a bottom plan view taken at “H” level of FIG. 27 according to one or more embodiments.

In FIG. 41, the semiconductor residue layer 10S and the additional semiconductor residue layer 10R may form the passage of leakage current between the adjacent first and second backside source/drain contact structures 80a and 80b. In FIG. 42, even if the semiconductor residue layer 10S is formed between the adjacent first and second backside source/drain contact structure 80a and 80b, the passage of leakage current may be blocked by the presence of the electrical insulating layer 76. Furthermore, according to one or more embodiments, even if the additional semiconductor residue layer 10R as well as the semiconductor residue layer 10S remains between the adjacent first and second backside source/drain contact structure 80a and 80b, the passage of leakage current may be blocked by the presence of the electrical insulating layer 76. Therefore, by blocking the passage of leakage current, the reliability of the operation of the integrated circuit device may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An integrated circuit device, comprising:
an insulating structure;
a first source/drain region on the insulating structure;
a gate structure comprising at least one gate electrode layer, the gate structure adjacent to the first source/drain region on the insulating structure;
a contact plug connected to the gate structure;
a backside source/drain contact structure penetrating the insulating structure and connected to the first source/drain region;
an electrical insulating layer on a side wall of an end portion of the backside source/drain contact structure, the electrical insulating layer contacting the first source/drain region; and
a semiconductor material layer on the electrical insulating layer,
wherein the electrical insulating layer is configured to electrically insulate the semiconductor material layer from the backside source/drain contact structure.

2. The integrated circuit device of claim 1, wherein the semiconductor material layer comprises a silicon layer, and
wherein the electrical insulating layer comprises a silicon oxide layer, a silicon nitride layer, or a silicon oxynitride layer.

3. The integrated circuit device of claim 1, wherein the electrical insulating layer is an insulating layer converted from the semiconductor material layer.

4. The integrated circuit device of claim 1, further comprisinga silicide layer between the backside source/drain contact structure and the first source/drain region.

5. The integrated circuit device of claim 1, wherein the at least one gate electrode layer comprises a plurality of gate electrode layers stacked in a vertical direction,
wherein the integrated circuit device comprises a plurality of nanosheets, and
wherein the plurality of nanosheets are respectively between the plurality of gate electrode layers.

6. The integrated circuit device of claim 1, further comprising:
a second source/drain region that is spaced apart from the first source/drain region, wherein the gate structure is between the first source/drain region and the second source/drain region; and
a frontside source/drain contact structure connected to the second source/drain region.

7. The integrated circuit device of claim 6, wherein the second source/drain region comprises a protruding portion that protrudes downward from an upper surface of the insulating structure into the insulating structure.

8. The integrated circuit device of claim 7, wherein the protruding portion comprises a material that is the same as a material of the second source/drain region.

9. The integrated circuit device of claim 7, wherein the protruding portion further comprises a place holder layer that comprises a material that is different from a material of the second source/drain region.

10. The integrated circuit device of claim 7, wherein at least a portion of the semiconductor material layer is on a side of the protruding portion of the second source/drain region.

11. The integrated circuit device of claim 7, wherein the semiconductor material layer is a continuous layer on a side of the protruding portion of the second source/drain region.

12. The integrated circuit device of claim 7, wherein at least a portion of the protruding portion is on the side wall of the end portion of the backside source/drain contact structure.

13. An integrated circuit device, comprising:
an insulating structure;
a first source/drain region on the insulating structure;
a second source/drain region on the insulating structure and spaced apart from the first source/drain region;
a gate structure comprising at least one gate electrode layer, the gate structure being between the first source/drain region and the second source/drain region;
a contact plug connected to the gate structure;
a first backside source/drain contact structure penetrating the insulating structure and connected to the first source/drain region;
an electrical insulating layer on a side wall of an end portion of the first backside source/drain contact structure, the electrical insulating layer contacting the first source/drain region; and
a first semiconductor material layer on the electrical insulating layer,
wherein the electrical insulating layer is configured to electrically insulate the first semiconductor material layer from the first backside source/drain contact structure.

14. The integrated circuit device of claim 13, wherein the first semiconductor material layer comprises a silicon layer, and
wherein the electrical insulating layer comprises a silicon oxide layer, a silicon nitride layer, or a silicon oxynitride layer.

15. The integrated circuit device of claim 13, wherein the at least one gate electrode layer comprises a plurality of gate electrode layers stacked in a vertical direction,
wherein the integrated circuit device comprises a plurality of nanosheets, and
wherein the plurality of nanosheets are respectively between the plurality of gate electrode layers.

16. The integrated circuit device of claim 13, further comprising a second backside source/drain contact structure penetrating the insulating structure and is connected to the second source/drain region,
wherein the electrical insulating layer is on a side wall of an end portion of the second backside source/drain contact structure and contacts the second source/drain region.

17. The integrated circuit device of claim 16, wherein the electrical insulating layer is configured to electrically insulate the first backside source/drain contact structure from the second backside source/drain contact structure.

18. The integrated circuit device of claim 17, further comprising a second semiconductor material layer that is a continuous layer between the electrical insulating layer on the side wall of the end portion of the first backside source/drain contact structure and the electrical insulating layer on the side wall of the end portion of the second backside source/drain contact structure.

19. The integrated circuit device of claim 13, further comprising a frontside source/drain contact structure connected to the second source/drain region.

20. An integrated circuit device, comprising:
an insulating structure;
a first source/drain region on the insulating structure;
a second source/drain region on the insulating structure and spaced apart from the first source/drain region;
a gate structure comprising a gate electrode layer, the gate structure being between the first source/drain region and the second source/drain region;
a contact plug connected to the gate structure;
a first backside source/drain contact structure penetrating the insulating structure and connected to the first source/drain region;
a second backside source/drain contact structure penetrating the insulating structure and connected to the second source/drain region;
an electrical insulating layer on at least one of a side wall of an end portion of the first backside source/drain contact structure and a side wall of an end portion of the second backside source/drain contact structure; and
a semiconductor material layer on the electrical insulating layer,
wherein at least a portion of the semiconductor material layer having a thickness less than 2 nm is on the insulating structure between the first backside source/drain contact structure and the second backside source/drain contact structure.
